(19) United States
(12) Patent Application Publication
(10) Pub. No.: US 2014/0331933 A1
(43) Pub. Date: Nov. 13, 2014

(54) APPARATUS FOR PROCESSING APPARATUS HAVING SIDE PUMPING TYPE

(71) Applicant: EUGENE TECHNOLOGY CO., LTD., Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yang-Sik Shin, Gyeonggi-do (KR)

(73) Assignee: EUGENE TECHNOLOGY CO., LTD., Gyeonggi-do (KR)

(21) Appl. No.: 14/370,040

(22) PCT Filed: Nov. 23, 2012
(86) PCT No.: PCT/KR2012/009953

§ 371 Date: Jun. 30, 2014

(30) Foreign Application Priority Data
Feb. 3, 2012 (KR) 10-2012-0011175

(51) Int. Cl. C23C 16/44; C23C 16/52; C23C 16/455

(52) U.S. Cl. CPC C23C 16/4412; C23C 16/45565; C23C 16/52
USPC 118/729; 118/715

(57) ABSTRACT

Provided is a substrate processing apparatus. The substrate processing apparatus includes a chamber body having an opened upper side, the chamber body providing an inner space in which a process with respect to a substrate is performed, a chamber lid disposed on an upper portion of the chamber body to close the opened upper side of the chamber body, and a showerhead disposed on a lower portion of the chamber lid to supply a process gas toward the inner space. The chamber body includes at least one convergent port disposed along the inside of a sidewall of the chamber body to allow the process gas within the inner space to converge, a plurality of inner exhaust holes defined in along the sidewall of the chamber body to communicate with the convergent port and the inner space, and a plurality of inner exhaust ports connected to the convergent port.

### BACKGROUND OF THE INVENTION

The present invention disclosed herein relates to a substrate processing apparatus, and more particularly, to a substrate processing apparatus having a side pumping type.

Semiconductor devices and flat panel displays are manufactured using a plurality of thin film deposition processes and etching processes. That is, a thin film is formed on a substrate through a deposition process, and then, unnecessary portions of the thin film are removed through an etching process using a mask. Thus, a desired predetermined pattern or circuit device is formed on the substrate.

The deposition process may be performed within a process chamber under a vacuum atmosphere. The substrate is loaded into the process chamber. A showerhead is disposed above the substrate to supply a process gas onto the substrate. The process gas is deposited on the substrate to form a desired thin film.

The deposition process is performed together with an exhaust process. In the exhaust process, process byproducts and non-reaction gases which are generated in the deposition process are discharged to the outside.

### SUMMARY OF THE INVENTION

The present invention provides a substrate processing apparatus having a side pumping type.

The present invention also provides a substrate processing apparatus which secures uniformity of a thin film deposited on a substrate through uniform exhaust.

Further another object of the present invention will become evident with reference to following detailed descriptions and accompanying drawings.

Embodiments of the present invention provide substrate processing apparatuses including: a chamber body having an opened upper side, the chamber body providing an inner space in which a process with respect to a substrate is performed; a chamber lid disposed on an upper portion of the chamber body to close the opened upper side of the chamber body; and a showerhead disposed on a lower portion of the chamber lid to supply a process gas toward the inner space, wherein the chamber body includes: at least one convergent port disposed along the inside of a sidewall of the chamber body to allow the process gas within the inner space to converge; a plurality of inner exhaust holes defined in along the sidewall of the chamber body to communicate with the convergent port and the inner space; and a plurality of inner exhaust ports connected to the convergent port.

In some embodiments, the substrate processing apparatuses may further include a susceptor on which the substrate is loaded on a top surface thereof, the susceptor being changeable in position through elevation thereof between a loading position at which the substrate is loaded and a process position at which the process with respect to the substrate is performed, and the inner exhaust holes may be disposed between an upper portion of the susceptor disposed at the process position and the showerhead.

In other embodiments, the chamber body may have a passage defined in the sidewall thereof to allow the substrate to enter into the inner space therethrough, and the convergent port and the inner exhaust holes may have disposed above the passage.

In still other embodiments, the inner exhaust holes may have diameters different from each other according to distances spaced apart from the inner exhaust ports.

In even other embodiments, the inner exhaust holes may have diameters proportional to distances spaced apart from the inner exhaust ports.

In yet other embodiments, the substrate processing apparatuses may further include a distribution ring disposed on the convergent port, the distribution ring having a plurality of distribution holes.

In further embodiments, the distribution holes may have diameters different from each other according to distances spaced apart from the inner exhaust ports.

In still further embodiments, the distribution holes may have diameters proportional to distances spaced apart from the inner exhaust ports.

In even further embodiments, the distribution holes may be disposed between the inner exhaust holes, respectively.

In yet further embodiments, the convergent port may have a ring shape.

In much further embodiments, the convergent port may be recessed from a top surface of the chamber body.

In still much further embodiments, the substrate processing apparatuses may further include a port cover closing an opened upper side of the convergent port.

In even much further embodiments, the substrate processing apparatuses may further include: a plurality of outer exhaust ports connected to the inner exhaust ports through the outside of the chamber body, respectively; and a main port connected to the outer exhaust ports.

In yet much further embodiments, the substrate processing apparatuses may further include: flow control valves respectively disposed on the outer exhaust ports to control a flow rate of the process gas discharged through the outer exhaust ports; and a controller connected to the flow control valves to control the flow control valves, thereby uniformly adjusting a discharge amount of the process gas.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic view of a substrate processing apparatus according to an embodiment of the present invention;

FIG. 2 is a cross-sectional view illustrating inner exhaust holes, a distribution ring, and inner exhaust ports of FIG. 1;

FIG. 3 is a view illustrating a lower portion of a chamber body of FIG. 1;

FIGS. 4 and 5 are views illustrating a flow of a process gas; and

FIG. 6 is a schematic view of a substrate processing apparatus according to another embodiment of the present invention.

### DETAILED DESCRIPTION OF PREFERRED EMBODIMENTS

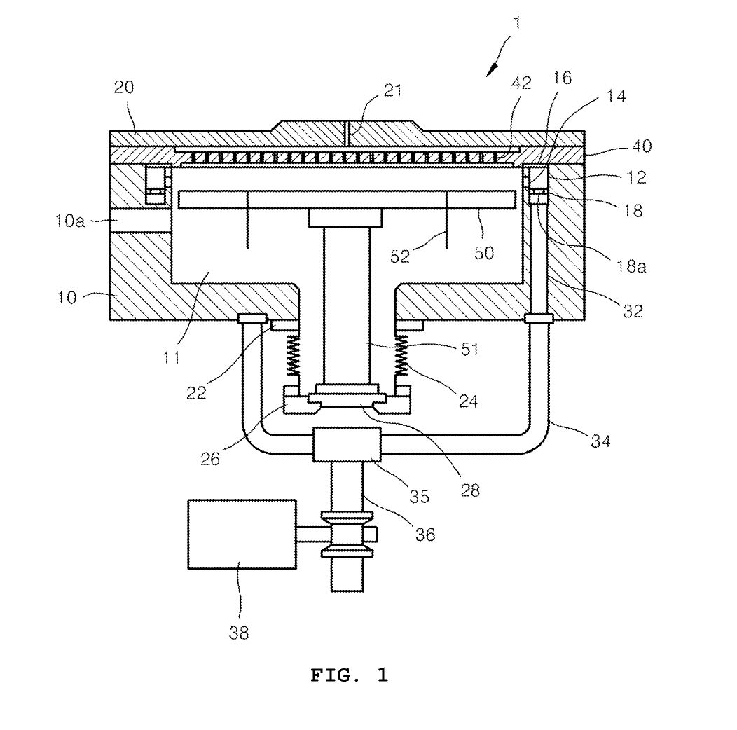

Hereinafter, exemplary embodiments of the present invention will be described in detail with reference to FIGS. 1 to 6. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

Although a deposition device is described below as an example, the present invention may be applicable to various substrate processing apparatuses. Also, although a wafer W is described below as an example, the present invention may be applicable to various objects to be processed.

FIG. 1 is a schematic view of a substrate processing apparatus according to an embodiment of the present invention. Referring to FIG. 1, a substrate processing apparatus 1 includes a chamber body 10 and a chamber lid 20. The chamber body 10 has an opened upper side. The chamber lid 20 opens or closes the opened upper side of the chamber body 10. When the chamber lid 20 closes the opened upper side of the chamber body 10, the chamber body 10 and the chamber lid 20 define an inner space closed against the outside.

The chamber body 10 has a chamber interior 11 corresponding to the inner space. A wafer is loaded into the chamber interior 11 through a passage 10a defined in a side of the chamber body 10. A susceptor 50 is disposed in the chamber interior 11. The loaded wafer is placed on a top surface of the susceptor 50. A rotation shaft 51 is connected to a lower portion of the susceptor 50. The rotation shaft 51 supports the susceptor 50 and rotates the susceptor 50 while processes are performed. A thin film is deposited on the wafer by the processes. The thin film may have a uniform thickness.

As shown in FIG. 1, a showerhead 40 has a flat plate shape and is disposed between the chamber body 10 and the chamber lid 20. Thus, the opened upper side of the chamber body 10 is closed by the showerhead 40 and the chamber lid 20. Alternatively, the showerhead 40 may be fixed to a bottom surface of the chamber lid 20 through a separate coupling member. Here, the opened upper side of the chamber body 10 may be closed by the chamber lid 20.

A gas supply port 21 is disposed within the chamber lid 20. A process gas is supplied through the gas supply port 21. The showerhead 40 has a concave top surface. The concave top surface is spaced apart from a bottom surface of the chamber lid 20 to define a buffer space. The process gas is filled into the buffer space through the gas supply port 21 and supplied into the chamber interior 11 through the showerhead 40. The showerhead 40 has a plurality of injection holes 42. The process gas is injected into the chamber interior 11 through the injection holes 42. The process gas is moved onto a surface of the wafer to form a thin film on the surface of the wafer. The process gas may be selected according to a kind of thin film.

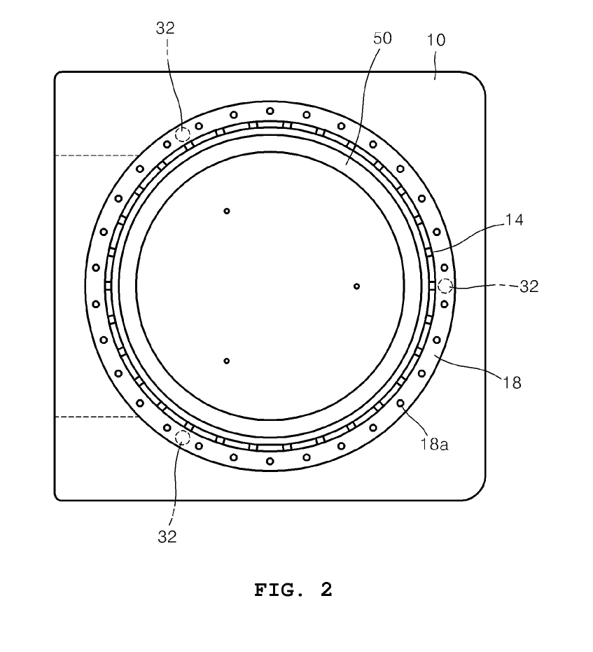

FIG. 2 is a cross-sectional view illustrating inner exhaust holes, a distribution ring, and inner exhaust ports of FIG. 1. The chamber body 10 includes a convergent port 12, inner exhaust holes 14, and inner exhaust ports. The convergent port 12 is disposed on a sidewall of the chamber body 10. The sidewall of the chamber body 10 is surrounded by the susceptor 50. The convergent port 12 is recessed from a top surface of the chamber body 10. A port cover 16 closes an opened upper side of the convergent port 12. Unlike the current embodiment, the opened upper side of the convergent port 12 may be closed by the chamber lid 20.

The convergent port 12 has a ring shape. Also, the convergent port 12 is disposed along the sidewall of the chamber body 10. The convergent port 12 is disposed above the passage 10a. Although the convergent port 12 having the ring shape is illustrated in FIG. 2, the present invention is not limited thereto. For example, the convergent port 12 may be provided as a plurality of divided parts, and also have a ring shape on the whole. In case of a substrate having a square shape, but a circular wafer, the convergent 12 may have a square ring shape.

The inner exhaust holes 14 are spaced apart from each other along the sidewall of the chamber body 10 to communicate with the convergent port 12 and the chamber interior 11. Byproducts and non-reaction gases generated during the processes may be introduced into the convergent port 12 through the inner exhaust holes 14. Each of the inner exhaust ports 32 is connected to the convergent port 12 and extends toward a lower portion of the chamber body 10. Thus, the byproducts and the non-reaction gases may be movable from the convergent port 12 into the inner exhaust ports 32. Then, the byproducts and the non-reaction gases may be discharged to the outside of the chamber body 10 through the inner exhaust ports 32.

As shown in FIG. 1, a distribution ring 18 is disposed on the convergent port 12. The distribution ring 18 may have a plurality of distribution holes 18a. As shown in FIG. 2, the distribution holes 18a may be disposed between the inner exhaust holes 14. The distribution ring 18 may have substantially the same shape as the convergent port 12. Also, the distribution ring 18 may have a ring shape disposed along the sidewall of the chamber body 10. As described above, when the convergent port 12 is provided as the plurality of divided parts, the distribution ring 18 may be divided and respectively disposed on the convergent ports 12. The byproducts and the non-reaction gases may be introduced into the convergent port 12, and then moved into the inner exhaust ports 32 through the distribution holes 18a.

As shown in FIG. 2, the inner exhaust ports 32 may be equangularly disposed (e.g., an angle of about) 120° with respect to a center of the susceptor 50 (or the substrate placed on the susceptor 50). Thus, when the byproducts of the chamber interior 11 are forcibly discharged through the inner exhaust ports 32, pressures supplied to the inner exhaust ports 32 may be uniformly balanced without being concentrated in any direction. Unlike the current embodiment, two inner exhaust ports 32 or at least four inner exhaust ports 32 may be provided.

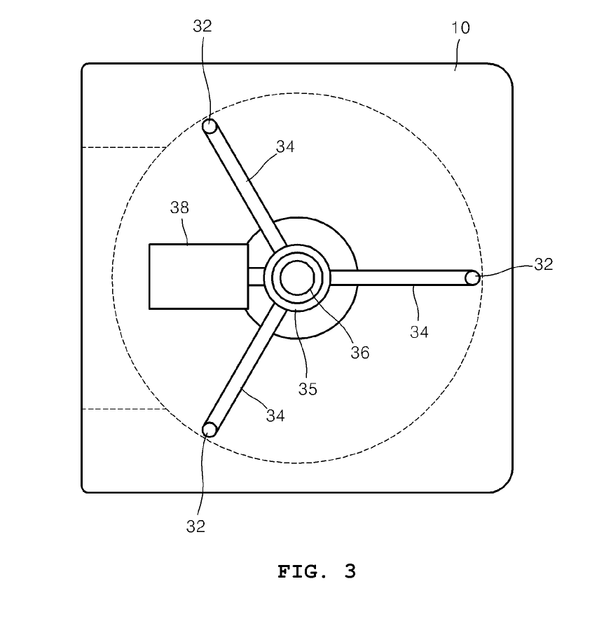

FIG. 3 is a view illustrating a lower portion of a chamber body of FIG. 1.

Outer exhaust ports 34 are connected to the inner exhaust ports 32, respectively. A main port 36 is connected to the outer exhaust ports 34 through a connection port 35. The main port 36 may be connected to an exhaust pump (not shown). When the exhaust pump is operated, the main port 36 (or the outer exhaust ports 34) having a relatively low pressure and the chamber interior 11 may have a pressure difference therebetween. Thus, the byproducts are moved into the main port 36 through the inner exhaust ports 32 and the outer exhaust ports 34. A pressure control valve 38 is connected to the main port 36. The pressure control valve 38 partially or fully opens or closes the main port 36 to control a pressure of the chamber interior 11. Although the outer exhaust ports 34 are respectively connected to the inner exhaust ports 32 through the lower portion of the chamber body 10 in the current embodiment, the present invention is not limited thereto. For example, the outer exhaust ports 34 may be connected to the inner exhaust ports 32 through a side portion of the chamber body 10.

The rotation shaft 51 is connected to a support through the lower portion of the chamber body 10. The support 28 is seated on a lower connection part 26. The lower connection part 26 may be elevated by a separate driving device (not shown). Thus, the rotation shaft 51 may be elevated together with the support 28. An upper connection part 22 is connected to the lower portion of the chamber body 10. A bellows 24 is connected to each of the upper connection part 22 and the lower connection part 26 to close the chamber interior 11 against the outside. Thus, the chamber interior 11 may be maintained in a vacuum state regardless of the elevation of the lower connection part 26.

The susceptor 50 is elevated together with the rotation shaft 51. Thus, the susceptor 50 is changed in position between a position (“a loading position”) at which the wafer is loaded and a position (“a process position”) at which the processes with respect to the wafer are performed. The wafer is loaded into the chamber interior 11 through the passage 10a. Then, the wafer is placed on the top surface of the susceptor 50 disposed at the loading position. When the susceptor 50 is disposed at the loading position, the susceptor 50 may be disposed at a position lower than that of the passage 10a. The susceptor 50 ascends together with the rotation shaft 51 and is moved toward the showerhead 40. When the susceptor 50 is disposed close to the showerhead 40 (see FIG. 1), the processes with respect to the wafer may be performed. When the processes are completely performed, the susceptor 50 descends together with the rotation shaft 51 to return to the loading position. Then, the processed substrate may be unloaded to the outside of the chamber body 10.

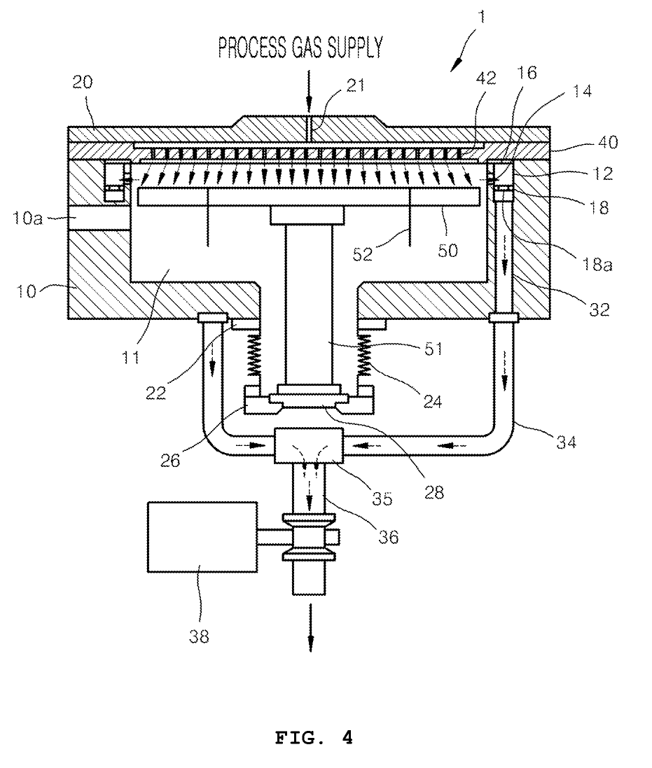

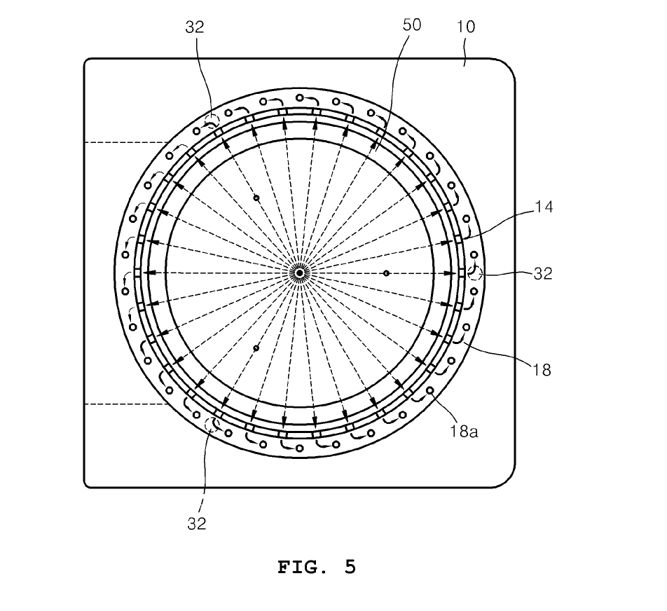

FIGS. 4 and 5 are views illustrating a flow of a process gas. When the processes are performed, the susceptor 50 ascends and is moved at the process position. Here, the susceptor 50 may be disposed at a position higher than that of the passage 10a. As described above, a process gas is filled into the buffer space through the gas supply port 21. Then, the process gas is injected onto a top surface of the susceptor 50 through the injection holes 42 of the showerhead 40. The process gas is moved to a surface of a wafer placed on the susceptor 50 to form a thin film on the surface of the wafer.

The exhaust pump may be operated while the processes are performed to discharge the byproducts and the non-reaction gases to the outside by the pressure difference between the chamber interior 11 and the main port 36 (or the outer exhaust ports 34). The convergent port 12 is disposed around the susceptor 50 disposed at the process position. Referring to FIGS. 4 and 5, the byproducts and the non-reaction gases which are generated during the processes are moved in a radius direction of the susceptor 50 and then introduced into the convergent port 12 through the inner exhaust holes 14. That is, the process gas injected toward the susceptor 50 is moved onto the surface of the wafer, and simultaneously, passes through the closest inner exhaust holes 14 as the byproducts and the non-reaction gases and then is introduced into the convergent port 12. Then, the process gas is moved to the closest inner exhaust ports 32 as the byproducts and the non-reaction gases.

Here, in a state where the susceptor 50 approaches the showerhead 40, the inner exhaust holes 14 are disposed between the showerhead 40 and the susceptor 50. The process gas is supplied between the susceptor 50 and the showerhead 40 to form the thin film on the surface of the wafer. Then, the process gas is moved into the convergent port 12 through the inner exhaust holes 14 as the byproducts. The process gas or the byproducts may not be moved toward a lower side of the susceptor 50, and a region in which the process gas is diffused may be minimized. Thus, the byproducts may be quickly discharged. Particularly, it may prevent the byproducts from being deposited on an inner wall of the chamber body 10 disposed under the susceptor 50. On the other hand, in a case of bottom pumping, an exhaust device is connected to the lower portion of the chamber body 10 to discharge the byproducts through the lower side of the susceptor 50. Thus, a region in which the process gas is diffused may be increased, and also, the byproducts are not quickly discharged. In addition, the byproducts may be deposited on the inner wall of the chamber body 10.

The inside of the main port 36 may have a low pressure by the exhaust pump. The low pressure may be dispersed into the outer exhaust ports 34 and the inner exhaust ports 32. Similarly, the low pressure within the inner exhaust ports 32 may be dispersed within the convergent port 12 through the distribution holes 18a of the distribution ring 18 and then be uniformly transferred into the chamber interior 11 through the inner exhaust holes 14. That is, a pressure difference between the chamber interior 11 and the main port 36 (or the inner exhaust ports 32) is not concentrated into a predetermined position of the chamber interior 11.

Thus, as shown in FIG. 5, the process gas or the byproducts may be uniformly discharged through the inner exhaust holes 14.

Particularly, since the distribution holes 18a are disposed between the inner exhaust holes 14, the pressure difference between the insides of the inner exhaust ports 32 and the chamber interior 11 may be more effectively dispersed. That is, since the low pressure within one distribution hole 18a is transferred into two inner exhaust holes 14, a pressure dispersion effect through the arrangement of the distribution holes 18a may be maximized

The uniform discharge of the byproducts of the chamber interior 11 regardless of the position of the susceptor 50 may closely relate to deposition uniformity. The deposition uniformity may be achieved by a uniform flow of the process gas. Also, the uniform flow of the process gas may be achieved according to exhaust uniformity.

Although each of the inner exhaust holes 14 and the distribution holes 18a has the same diameter in FIGS. 2 and 5, the present invention is not limited thereto. For example, the inner exhaust holes 14 and the distribution holes 18a may have diameters different from each other to more uniformly discharge the byproducts. That is, since the inner exhaust ports 32 are provided, the byproducts may be concentrated in directions (three directions) of the inner exhaust ports 32. Thus, a relatively large amount of byproducts may be discharged in the directions of the inner exhaust ports 32 when compared to directions except for the directions of the inner exhaust ports 32. Thus, the inner exhaust holes 14 or the distribution holes 18a may have different diameters according to distances spaced apart from the inner exhaust ports 32. Also, the inner exhaust holes 14 or the distribution holes 18a may have diameters proportional to distances spaced apart from the inner exhaust ports 32.

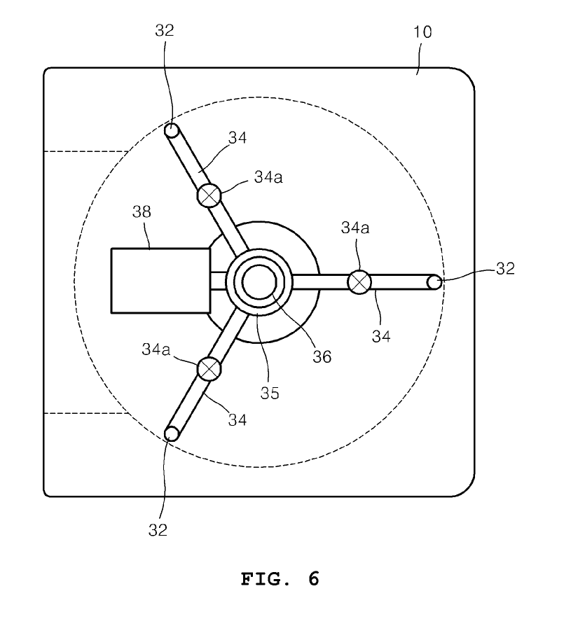

FIG. 6 is a schematic view of a substrate processing apparatus according to another embodiment of the present invention. Flow control valves 34a may be disposed in the outer exhaust ports 34, respectively. The flow control valves 34a may open or close the outer exhaust ports 34 to control a flow rate, respectively. A controller (not shown) may be connected to each of the flow control valves 34a to control the flow control valves 34a. That is, the controller may uniformly adjust gas flow rates of the outer exhaust ports 34 to uniformly discharge the byproducts through the outer exhaust ports 34.

According to the present invention, the byproducts and the non-reaction gases may be discharged to the outside of the process chamber through the side pumping type. Particularly, the uniformity of the thin film deposited on the substrate may be secured through the uniform exhaust.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate processing apparatus comprising:
a chamber body having an opened upper side, the chamber body providing an inner space in which a process with respect to a substrate is performed;
a chamber lid disposed on an upper portion of the chamber body to close the opened upper side of the chamber body; and
a showerhead disposed on a lower portion of the chamber lid to supply a process gas toward the inner space,
wherein the chamber body comprises:
at least one convergent port disposed along the inside of a sidewall of the chamber body to allow the process gas within the inner space to converge;
a plurality of inner exhaust holes defined in along the sidewall of the chamber body to communicate with the convergent port and the inner space; and
a plurality of inner exhaust ports connected to the convergent port.

2. The substrate processing apparatus of claim 1, further comprising a susceptor on which the substrate is loaded on a top surface thereof, the susceptor being changeable in position through elevation thereof between a loading position at which the substrate is loaded and a process position at which the process with respect to the substrate is performed, and
the inner exhaust holes are disposed between an upper portion of the susceptor disposed at the process position and the showerhead.

3. The substrate processing apparatus of claim 1, wherein the chamber body has a passage defined in the sidewall thereof to allow the substrate to enter into the inner space therethrough, and
the convergent port and the inner exhaust holes are disposed above the passage.

4. The substrate processing apparatus of claim 1, wherein the inner exhaust holes have diameters different from each other according to distances spaced apart from the inner exhaust ports.

5. The substrate processing apparatus of claim 1, wherein the inner exhaust holes have diameters proportional to distances spaced apart from the inner exhaust ports.

6. The substrate processing apparatus of claim 1, further comprising a distribution ring disposed on the convergent port, the distribution ring having a plurality of distribution holes.

7. The substrate processing apparatus of claim 6, wherein the distribution holes have diameters different from each other according to distances spaced apart from the inner exhaust ports.

8. The substrate processing apparatus of claim 6, wherein the distribution holes have diameters proportional to distances spaced apart from the inner exhaust ports.

9. The substrate processing apparatus of claim 6, wherein the distribution holes are disposed between the inner exhaust holes, respectively.

10. The substrate processing apparatus of claim 1, wherein the convergent port has a ring shape.

11. The substrate processing apparatus of claim 1, wherein the convergent port is recessed from a top surface of the chamber body.

12. The substrate processing apparatus of claim 11, further comprising a port cover closing an opened upper side of the convergent port.

13. The substrate processing apparatus of claim 1, further comprising:
a plurality of outer exhaust ports connected to the inner exhaust ports through the outside of the chamber body, respectively; and
a main port connected to the outer exhaust ports.

14. The substrate processing apparatus of claim 13, further comprising:
flow control valves respectively disposed on the outer exhaust ports to control a flow rate of the process gas discharged through the outer exhaust ports; and
a controller connected to the flow control valves to control the flow control valves, thereby uniformly adjusting a discharge amount of the process gas.
